(19) United States
(12) Patent Application Publication
(10) Pub. No.: US 2007/0210331 A1
(43) Pub. Date: Sep. 13, 2007

(54) Guard ring applied to ion implantation equipment

(76) Inventor: Yu Da Chen, Jubei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/369,828

(22) Filed: Mar. 8, 2006

(51) Int. Cl. H01L 31/00

(52) U.S. Cl. 257/186

(57) ABSTRACT

A guard ring applied to an ion implantation equipment is disposed between a bushing and an ion beam source housing of the ion implantation equipment. The guard ring is made of high-density ceramic material. The guard ring can prevent arcing generated by the high voltage used for ion implantation from causing unpredicted damage to the bushing, thereby effectively protecting the ion implantation equipment, increasing the lifetime of use of the ion implantation equipment, and lengthening the maintenance cycle.

### BACKGROUND OF THE INVENTION

1. Field of the Invention

The present invention relates to an improved ion implantation equipment used in the semiconductor manufacturing process and, more particularly, to a guard ring applied to an ion implantation equipment to prevent arcing from puncturing the ion implantation equipment.

2. Description of Related art

In the semiconductor IC manufacturing process, products are processed by an ion implantation equipments for about 10 to 20 times. Ions are formed by ionizing molecules or atoms, and carry a certain electric charges. Ions are usually accelerated by an electric field to possess a high energy, and are deflected by a magnetic field and finally implanted into semiconductor wafers.

An ion implantation equipment mainly comprises a power system, an ion implantation source device, a magnetic field generator, a vacuum system, an air compressor, laminar air flow station, a safety device, and a cooling system. FIG. 1 is diagram of a conventional ion implantation source device. Because ions will bombard the connection between a bushing 34 and an ion beam source housing 36 of an ion implantation source device 38 for a long time during ion implantation to cause unpredicted damage, the operation of the whole equipment will be affected.

The primary reason why unpredicted damage occurs between the bushing 34 and the ion beam source housing 36 is that the high-voltage current used by the ion implantation device during ion implantation is too large, causing the generation of an arcing phenomenon to damage the bushing 34 and the ion beam source housing 36. This will also seriously affect the capacity of the manufacturing factory when an ion implanter performs ion implantation. Accordingly, the present invention aims to propose a guard ring applied to an ion implantation equipment to solve the above problems in the prior art.

### SUMMARY OF THE INVENTION

An object of the present invention is to provide a guard ring applied to an ion implantation equipment. The guard ring made of ceramic material is disposed between a bushing and an ion beam source housing of an ion Implantation source device to prevent arcing from causing unpredicted damage, thereby lengthening the maintenance cycle, increasing the lifetime of use, and enhancing the capacity utilization of the ion implantation equipment.

Another object of the present invention is to provide a guard ring applied to an ion implantation equipment, in which a guard sleeve extends downwards from the inside of the guard ring, and is disposed at the inside of the ion beam source housing. The guard sleeve can further effectively isolate arcing caused during the ionization process, hence securing normal operations of other components of the equipment.

To achieve the above objects, the present invention proposes a guard ring applied to an ion implantation equipment to solve the problem in the prior art that damage easily occurs between the bushing and the ion beam source housing. The guard ring is disposed between the bushing and the ion beam source housing of an ion implantation equipment by using a plurality of fixing holes on the guard ring. A plurality of first raised poles on the guard ring are joined with a plurality of corresponding first recessed holes on the ion beam source housing, and a plurality of second raised poles on the bushing are joined with a plurality of corresponding second recessed holes on the guard ring, hence accomplishing the positioning effect.

In the present invention, a guard sleeve can further extend inwards from the inside of the guard ring of the ion implantation equipment. The guard sleeve is located at the inside of the ion beam source housing. The guard sleeve can be integrally formed with the guard ring, or can be processed and assembled with the guard ring.

### BRIEF DESCRIPTION OF THE DRAWINGS

The various objects and advantages of the present invention will be more readily understood from the following detailed description when read in conjunction with the appended drawing, in which:

FIG. 1 is diagram of a conventional ion implantation source device;

FIG. 2 shows a perspective view and a partly enlarged view of a ring body of the present invention;

FIG. 3a is a top view of a guard ring applied to an ion implantation equipment of the present invention;

FIG. 3b is a side view of a guard ring applied to an ion implantation equipment of the present invention;

FIG. 4 is a cross-sectional view according to the first embodiment of the present invention shown in FIG. 2;

FIG. 5 is a perspective view of a guard ring having a guard sleeve of the present invention;

FIG. 6 is a cross-sectional view according to the second embodiment of the present invention shown in FIG. 5; and

FIG. 7 is a cross-sectional view according to a third embodiment of the present invention.

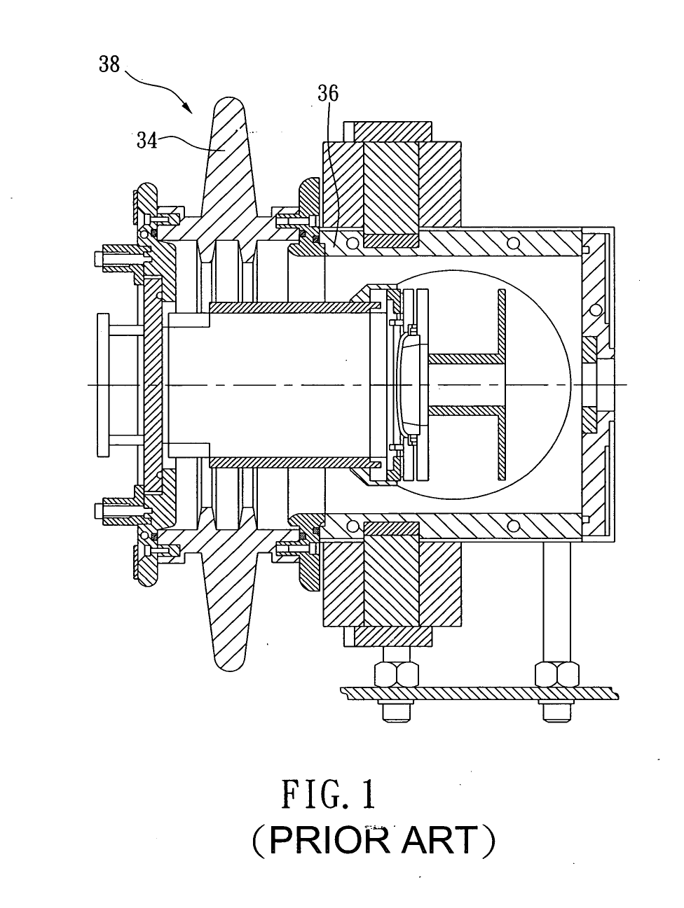

### DETAILED DESCRIPTION OF THE PREFERRED EMBODIMENTS

The present invention provides a guard ring applied to an ion implantation equipment. The guard ring is disposed between a bushing and an ion beam source housing of the ion implantation equipment to effectively prevent arcing generated by the high-voltage current used by the ion implantation device from puncturing components to cause damage to the ion implantation equipment. The arcing phenomenon will cause abnormal operation of the ion implantation equipment to seriously affect the capacity of the manufacturing factory.

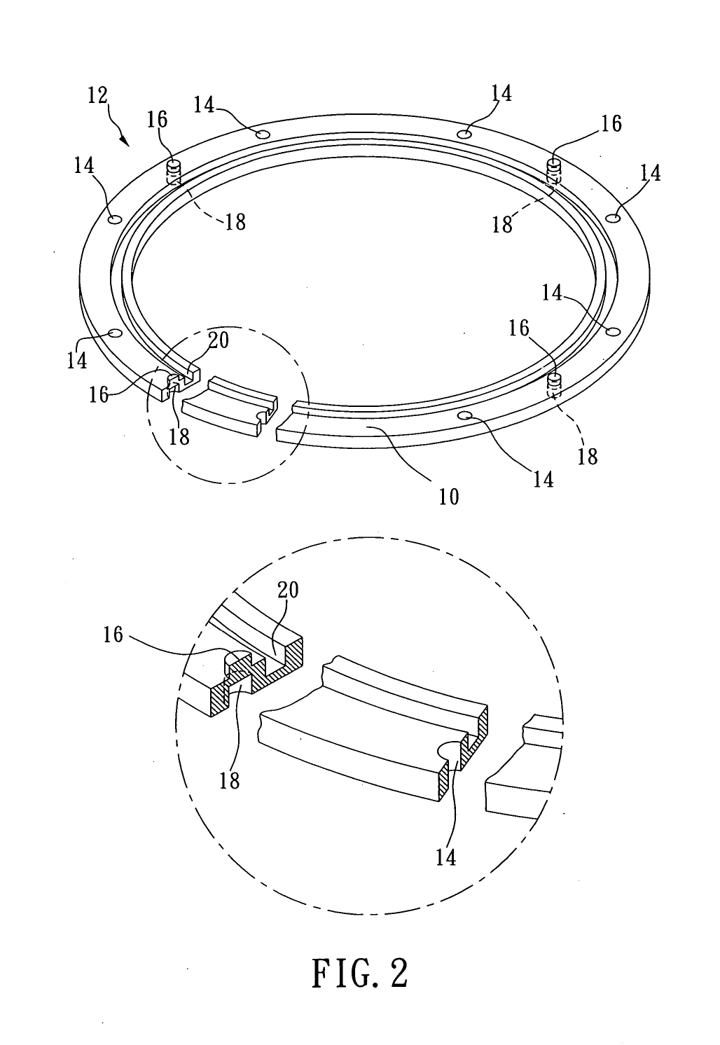

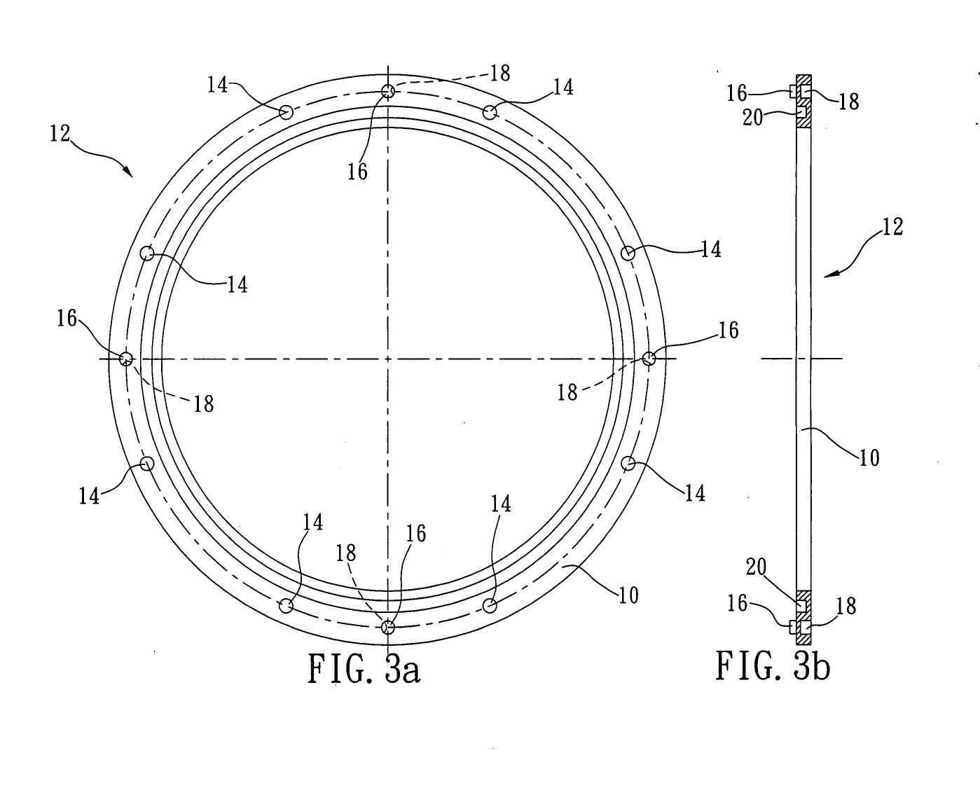

As shown in FIGS. 2, 3a and 3b, a guard ring 12 applied to an ion implantation equipment has a plurality of fixing holes 14, a plurality of first raised poles 16, a plurality of second recessed holes 18, and an annular groove 20 disposed on a ring body 10.

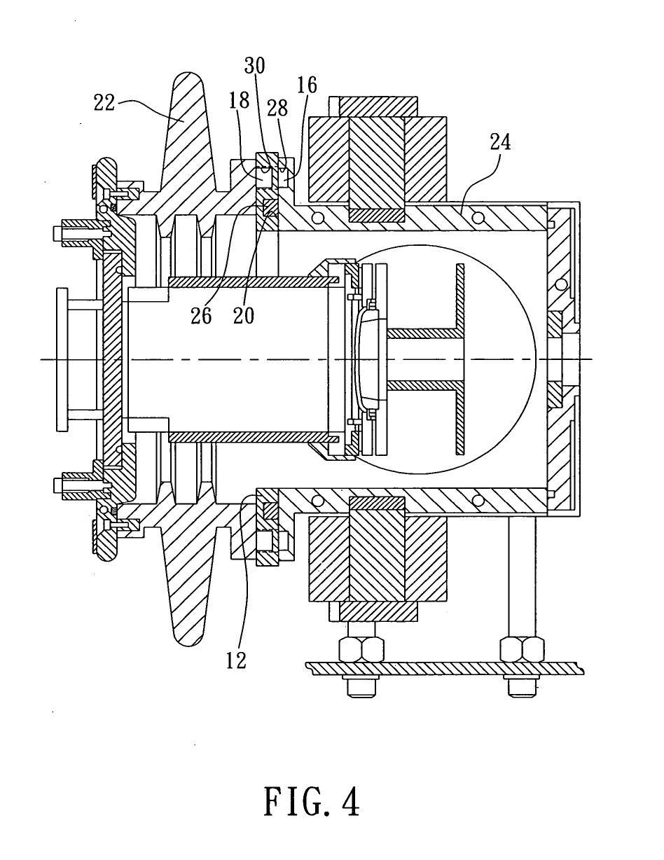

FIGS. 2 and 4 show a first embodiment of the present invention, in which a ring body 10 is disposed between a bushing 22 and an ion beam source housing 24 by using a plurality of fixing holes 14 on the ring body 10. An annular groove 20 is disposed on the ring body 10, and an annular raised bar 26 is correspondingly disposed on the ion beam source housing 24 so that the ring body 10 and the ion beam source housing 24 can be joined together. A plurality of first raised poles 16 are disposed on the ring body 10, and a plurality of first recessed holes 28 are correspondingly disposed on the ion beam source housing 24 so that the guard ring 12 can be positioned on the ion beam source housing 24. A plurality of second recessed holes 18 are disposed on the ring body 10, and a plurality of second raised poles 30 are correspondingly disposed on the bushing 2 so that the guard ring 12 can be positioned on the bushing 22. The fixing holes 14 are used to fix the guard ring 12 between the bushing 22 and the ion beam source housing 24.

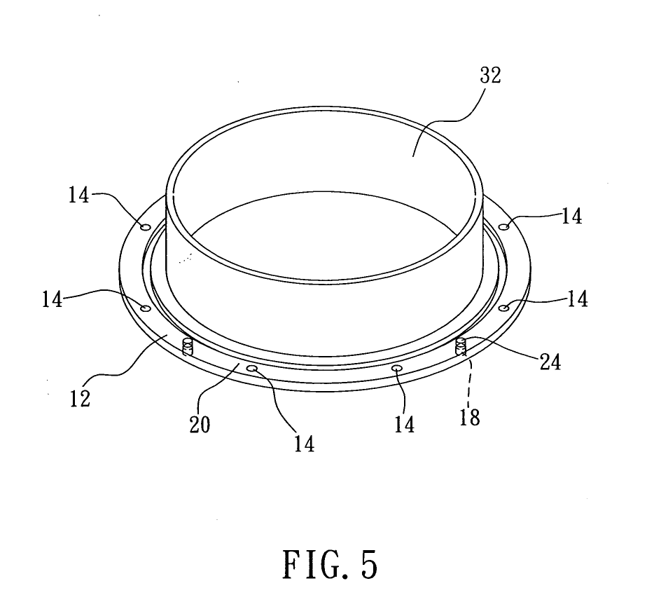

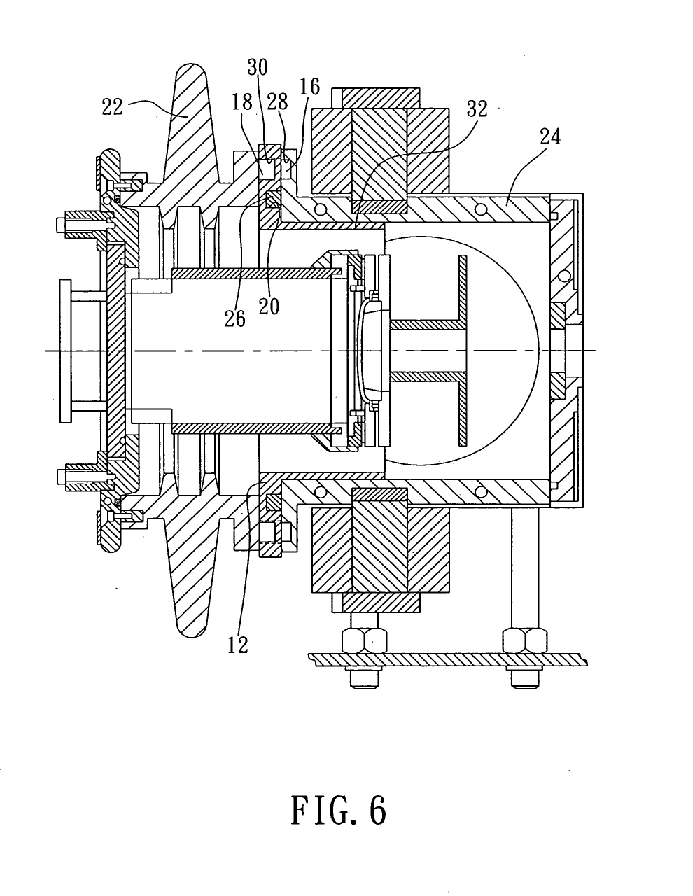

FIGS. 5 and 6 show a second embodiment of the present invention, in which a guard sleeve 32 extends inwards from the inside of the guard ring 12. The guard sleeve 32 is located at the inside of the ion beam source housing 24. The guard ring 12 and the guard sleeve 32 is integrally formed between the bushing 24 and the ion beam source housing 24 to facilitate detachment and interior cleaning.

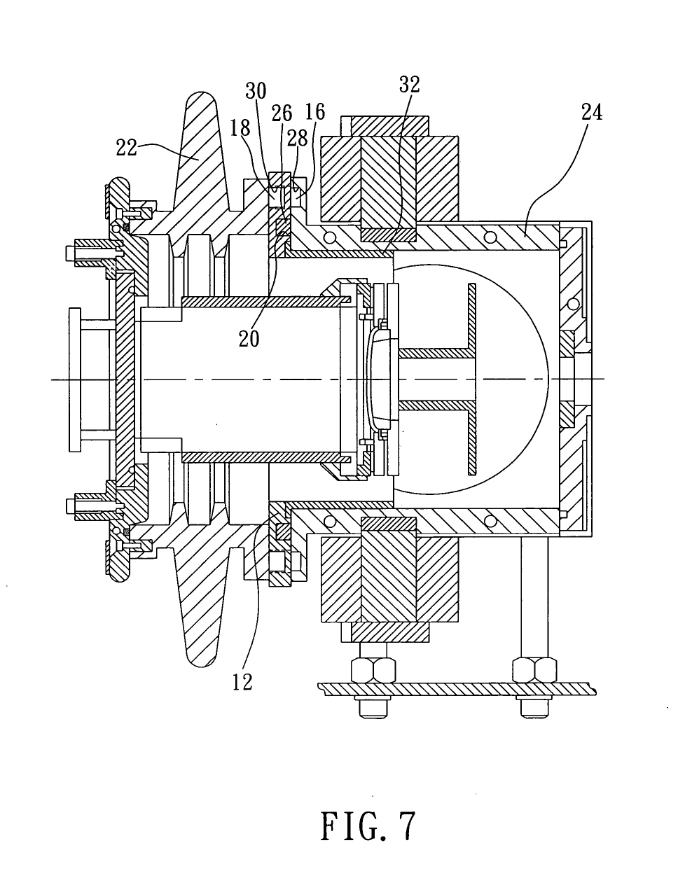

FIG. 7 shows a third embodiment of the present invention, in which the guard ring 12 and the guard sleeve 32 are processed and assembled together.

In the present invention, the guard ring 12 is made of high-density ceramic material composed of 99.7% aluminum oxide, 0.06% silicon oxide, 0.01% magnesium oxide, 0.01˜0.05% calcium oxide, and 0.01˜0.05% ferric oxide. The guard ring 12 can strengthen the connection between the ion beam source housing 24 and the bushing 22 to effectively prevent arcing from puncturing components of the equipment.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A guard ring applied to ion implantation equipment comprising a ring body with a plurality of fixing holes thereon, said guard ring being disposed between a bushing and an ion beam source housing of said ion implantation equipment by using said fixing holes.

2. The guard ring applied to ion implantation equipment as claimed in claim 1, wherein said guard ring is made of high-density ceramic material.

3. The guard ring applied to ion implantation equipment as claimed in claim 2, wherein said high-density ceramic material is composed of 99.7% aluminum oxide, 0.06% silicon oxide, 0.01% magnesium oxide, 0.01˜0.05% calcium oxide, and 0.01˜0.05% ferric oxide.

4. The guard ring applied to ion implantation equipment as claimed in claim 1, wherein an annular groove is disposed on said ring body, and an annular raised bar is correspondingly disposed on said ion beam source housing so that said ring body and said ion beam source housing can be joined together.

5. The guard ring applied to ion implantation equipment as claimed in claim 1, wherein a plurality of first raised poles are disposed on said ring body, and a plurality of first recessed holes are correspondingly disposed on said ion beam source housing so that said ring body can be positioned on said ion beam source housing.

6. The guard ring applied to ion implantation equipment as claimed in claim 1, wherein a plurality of second recessed holes are disposed on said ring body, and a plurality of second raised poles are correspondingly disposed on said bushing so that said ring body can be positioned on said bushing.

7. The guard ring applied to ion implantation equipment as claimed in claim 1, wherein a guard sleeve extends inwards from an inside of said ring body, and said guard sleeve is located at an inside of said ion beam source housing.

8. The guard ring applied to ion implantation equipment as claimed in claim 7, wherein said ring body and said guard sleeve are integrally formed.

9. The guard ring applied to ion implantation equipment as claimed in claim 7, wherein said ring body and said guard sleeve are processed and assembled together.
